(19) United States
(12) Patent Application Publication
(10) Pub. No.: US 2018/0334018 A1
(43) Pub. Date: Nov. 22, 2018

(54) SLIDING CONTACT CONTROL UNIT IN A CONTROL PANEL FOR A MOTOR VEHICLE

(71) Applicant: Delphi Technologies, LLC, Troy, MI (US)

(72) Inventor: Andrzej Polak, Huerth (DE)

(21) Appl. No.: 15/975,437

(22) Filed: May 9, 2018

(30) Foreign Application Priority Data
May 18, 2017 (FR) 1754425

(51) Int. Cl. B60J 7/057; B60K 37/06; G06F 3/01; G06F 3/02; H03K 17/96

(52) U.S. Cl. CPC B60J 7/0573; B60K 37/06; G06F 3/016; H03K 2217/96062; H03K 17/9622; B60K 2350/1024; G06F 3/0202

(57) ABSTRACT

A sliding-contact control unit for a motor vehicle includes a support element, a printed circuit board arranged on the support element, a control element covering the printed circuit board that defines an operator-controlled finger-slide control zone. The printed circuit board includes a first series of position detectors configured to determine the position and the direction of sliding of the finger of an operator. The first series of position detectors is supported against the control element, facing the slide-operated control zone. The printed circuit board includes a first detection element, which is simultaneously a contact force sensor and a haptic actuator, wherein the first detection element is interposed in a supporting arrangement between the printed circuit board and a connecting component, wherein the connecting component is in direct contact with the control element.

### TECHNICAL FIELD OF INVENTION

This disclosure generally relates to a sliding-contact control unit in a control panel for a motor vehicle, and more specifically to an operator-controlled finger-slide control button, with force feedback.

### BACKGROUND OF INVENTION

The occupants of a motor vehicle are highly sensitive to the visual appearance and the tactile quality of the control buttons on a control panel. In general, sliding-contact control buttons with force feedback, i.e. in which a finger-slide on the control zone of the button is detected and confirmed by a haptic effect, comprise conventional mechanical switches formed of moving parts. In general, conventional solutions such as spring-loaded push buttons are employed to generate a haptic effect. Control panels equipped with such sliding-contact control buttons are generally space-consuming and complex to manufacture.

### SUMMARY OF THE INVENTION

According to the invention, a sliding-contact control unit for a motor vehicle comprises a support element; a printed circuit board arranged on the support element; a control element covering the printed circuit board and comprising an operator-controlled finger-slide control zone; the printed circuit board comprising a first series of position detectors, configured to determine the position and the direction of sliding of the finger of an operator, wherein the first series of position detectors is supported against the control element, facing the slide-operated control zone. The printed circuit board comprises at least a first detection element, which is simultaneously a contact force sensor and a haptic actuator, wherein the first detection element is interposed in a supporting arrangement between the printed circuit board and a connecting component, wherein the connecting component is in direct contact with the control element.

The printed circuit board can incorporate a first cut-out, forming a first elastic tab upon which the first detection element is arranged. Each detection element is a piezoelectric element.

The first series of position detectors can comprise capacitive detection sensors. The printed circuit board can be of overall rectangular design, in one longitudinal axis and one transverse axis, wherein the control element can comprise a control plate of overall rectangular design, upon which the control zone extends longitudinally, in order to permit the detection of a finger-slide on the control zone in the longitudinal direction.

The transverse median zone of the printed circuit board can be supported on a transverse support bar, which incorporates a projecting profile on the support element, and the transverse edges of the printed circuit board can be flattened against the support element, such that the printed circuit board shows a curved profile.

A second series of position detectors can be arranged symmetrically to the first series of positon detectors in relation to the transverse median line of the printed circuit board, and a second detection element can be arranged symmetrically to the first detection element, in relation to the transverse median line of the printed circuit board.

The printed circuit board can incorporate a second cut-out, forming a second elastic tab upon which the second detection element is arranged. The connecting component can incorporate a first contact arm, formed in one piece with the control element and arranged against the first detection element and the second detection element.

The control unit may incorporate a third detection element and a fourth detection element, respectively arranged symmetrically to the first detection element and the second detection element, in relation to the longitudinal median line of the printed circuit board.

The printed circuit board can incorporate a third cut-out and a fourth cut-out, forming a third elastic tab and a fourth elastic tab upon which the third detection element and the fourth detection element are arranged.

The connecting component can comprise a second contact arm, formed in one piece with the control element and arranged against the third detection element and the fourth detection element. The connecting component can incorporate at least one position detector. The connecting component can incorporate at least one support bar having a projecting profile on the support element, wherein each detection element can be arranged on a support bar, and wherein the control element incorporates means of attachment to the support element.

The means of attachment may be retention pins, extending from the control element to their free end, wherein each free end incorporates a lug which engages in openings provided in the support element and abuts against the lower surface of the support element, such that the printed circuit board is retained by compression between the control element and the support element.

According to the invention, an electronic roof module in the passenger compartment of the motor vehicle incorporates the above-mentioned control unit.

According to the invention, a method for the control of a sliding-contact control unit of the above-mentioned type comprises the following steps: detection of finger contact with the control zone, by means of a capacitive detection sensor; confirmation of finger contact with the control zone, by means of a piezoelectric element; detection of the finger contact force on the control zone, by means of the piezoelectric element; detection of the finger-slide on the control zone, by means of a series of capacitive detection sensors; generation of a haptic acknowledgement signal for the finger-slide on the control zone, by means of the piezoelectric element; activation of a vehicle command, according to the route of the finger-slide on the control zone.

### BRIEF DESCRIPTION OF DRAWINGS

Further characteristics, purposes and advantages of the invention will proceed from the following detailed description, considered with reference to the attached drawings, which are provided by way of non-limiting examples, and in which:

FIG. 1 shows a partial schematic view, in perspective and in transverse section, of a control panel incorporating a sliding-contact control unit according to a first form of embodiment;

FIG. 2 shows an exploded perspective view of the sliding-contact control unit represented in FIG. 1;

FIG. 3 shows a partial schematic view, in perspective and in transverse section, of a control panel incorporating the sliding-contact control unit according to a second form of embodiment;

FIG. 4 shows an exploded perspective view of the sliding-contact control unit represented in FIG. 3;

FIG. 5 shows a partial schematic view, in perspective and in transverse section, of the control panel incorporating the sliding-contact control unit according to a third form of embodiment;

FIG. 6 shows an exploded perspective view of the sliding-contact control unit represented in FIG. 5;

FIG. 7 shows a partial schematic view, in perspective and in transverse section, of the control panel incorporating the sliding-contact control unit according to a fourth form of embodiment;

FIG. 8 shows an exploded perspective view of the sliding-contact control unit represented in FIG. 7; and

FIG. 9 shows a schematic view of an electronic roof module in a vehicle, incorporating the control panel equipped with a sliding-contact control unit according to any one of the forms of embodiment represented in the preceding figures.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

‘One or more’ includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for describing embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

In order to facilitate the description, and not by way of limitation, an orthogonal coordinate system is defined, comprising a longitudinal axis L, a transverse axis T and a vertical axis V. The orientations “down”, “up”, “above”, “below”, “lower” and “upper” are defined with reference to the vertical direction. The orientations “left”, “right” and “lateral” are defined with reference to the transverse direction. The orientations “front” and “rear” are also defined with reference to the longitudinal direction.

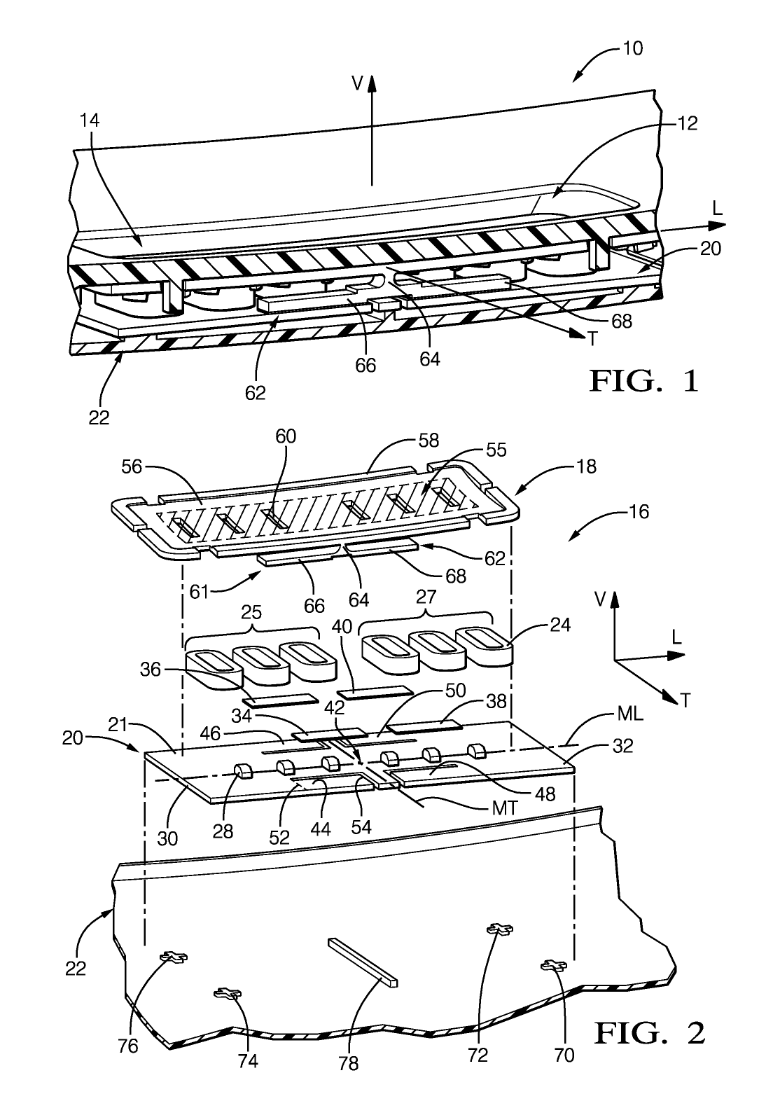

According to FIG. 1, a control panel 10 for a motor vehicle comprises a sliding-contact control button 12 arranged in the longitudinal axis L. A sliding-contact control button 12 is understood as a control button 12 in which the finger-slide applied by an operator to the button is detected, and actuates a function on the vehicle. The control panel 10 incorporates an opening 14 in which the control button 12 is arranged, thus permitting the operator to access the sliding-contact control button 12.

According to the form of embodiment represented, the finger-slide must be applied to the control button in the longitudinal axis.

According to FIG. 1 and FIG. 2, a first form of embodiment of the control button 12 is represented. The control button 12 is comprised of a control unit 16, comprising a control element 18 and a printed circuit board 20 arranged on a support element 22.

Overall, the printed circuit board 20 assumes a rectangular shape. The printed circuit board 20 comprises a series of position detectors 24, together with detection elements which combine the properties of a contact force sensor and a haptic actuator. More specifically, the series of position detectors 24 comprises sensors of the capacitive detection sensor type, and the detection elements 34 are piezoelectric elements. The piezoelectric elements are designed to act as contact force sensors, such that the mechanical deformation thereof by the application of contact can be converted into an electrical signal. The piezoelectric elements are also designed to act as a haptic actuator, such that the stimulation thereof by an electrical signal can initiate their vibration, wherein the vibrations are perceived as force feedback by the finger of the operator.

According to the form of embodiment represented, the position detectors 24 are aligned consecutively, one after another, in the longitudinal direction on the upper surface 21 of the printed circuit board 20. More specifically, the position detectors 24 are arranged on the longitudinal median line ML of the printed circuit board 20. In a non-limiting manner, the position detectors 24 are six in number. Overall, the six position detectors 24 are regularly divided into a first group 25 of three position detectors 24, extending from a first transverse end 30 of the printed circuit board 20 to the transverse median line MT of the printed circuit board 20, and a second group 27 of three position detectors 24, extending from the transverse median line MT of the printed circuit board 20 to the second transverse end 32 of the printed circuit board 20.

The position detectors 24 are annular in shape, and are thus also designed to serve as light guides for the light beams from light sources 28 arranged on the printed circuit board 20. Each of the light sources 28 is thus surrounded by a position detector 24.

In a non-limiting manner, the detection elements 34, 36, 38, 40 are piezoelectric elements of a rectangular overall shape, arranged on the upper surface 21 of the printed circuit board 20. The detection elements 34, 36, 38, 40 are four in number. The detection elements 34 are divided into a first pair of detection elements 34, 36, arranged longitudinally and symmetrically in relation to the longitudinal median line ML, at the longitudinal edge of the printed circuit board 20. The detection elements 34, 36, 38, 40 are also divided into a second pair of detection elements 38, 40, arranged symmetrically to the first pair 34, 36 in relation to the transverse median line MT of the printed circuit board 20. More specifically, the four detection elements 34, 36, 38, 40 are arranged in immediate proximity to the transverse median line MT of the printed circuit board 20. The two pairs of detection elements 34, 36, 38, 40 are therefore mutually separated by a zone of the printed circuit board, extending in the transverse median line MT of the printed circuit board. This zone will be described as the transverse median zone 42 of the printed circuit board 20.

In a particular manner, each detection element 34, 36, 38, 40 is arranged on an elastic tab 44, 46, 48, 50 of the printed circuit board 20. Each tab 44, 46, 48, 50 is formed by means of a cut-out in the printed circuit board 20. Each tab 44, 46, 48, 50 is of a rectangular overall shape, comprising three edges which are delimited by an interruption in the material, and a connecting end 52 to the printed circuit board 20. Each tab 44, 46, 48, 50 extends longitudinally, from its connecting end 52 to the printed circuit board 20 to its free end 54. The free ends 54 of the tabs 44, 46, 48, 50 are arranged in direct opposition to the transverse median line MT of the printed circuit board 20. The dimensions of each tab 44, 46, 48, 50, i.e. the length in the longitudinal axis L and the width in the transverse axis T, are of the same order of magnitude as the detection element 34, 36, 38, 40 arranged on said tab 44, 46, 48, 50.

In the same manner as the detection elements 34, 36, the tabs 44, 46 upon which the first pair of detection elements 34, 36 are arranged are mutually symmetrical to the longitudinal median line ML of the printed circuit board 20; the tabs 48, 50 upon which the second pair of detection elements 38, 40 are arranged are symmetrical, in relation to the transverse median line MT of the printed circuit board 20, to the tabs 48, 50 upon which the first pair of detection elements 34, 36 are arranged.

The control element 18 comprises an operator-controlled finger-slide control zone 55. The operator-controlled finger-slide control zone 55 is identified on FIG. 1 by a shaded area. The control zone 55 is arranged on a control plate 56 of the control element 18 of rectangular overall shape. The series of position detectors 24, i.e. the first group 25 and the second group 27, is mounted in contact against the control plate 56 and in opposition to the slide-operated control zone 55, such that a finger-slide on the control zone 55 is detected by the position detectors 24. The control element 18 incorporates, at the edge of the control plate 56, a liner 58 which permits the fitting thereof in the opening 14 in the control panel 10. The liner 58 forms a leak-tight seal between the control panel 10 and the control button 12.

The control element 18 incorporates, on the slide-operated control zone 55, openings 60 which are designed to be back-lit by light sources 28. The openings 60 which are designed for back-lighting can also be replaced by pictograms.

The control element 18 also comprises contact arms 62, which rest on the detection elements 34, 36, 38, 40. The contact arms 62 are in permanent contact with the detection elements 34, 36, 38, 40. According to the form of embodiment represented, the control element 18 comprises two contact arms 62 (only one of which is visible), wherein each contact arm 62 is in contact with two detection elements 34, 38 arranged in opposition on either side of the transverse median line MT of the printed circuit board 20. Each contact arm 62 assumes the overall form of an inverted “T”. Each central bar 64 of each “T” is arranged vertically on each longitudinal edge of the control plate 56, at the level of the transverse median line MT of the printed circuit board 20. The central bar 64 extends vertically downwards towards the transverse median zone of the printed circuit board 20. The central vertical bar 64 comprises two horizontal bars 66, 68 extending longitudinally on either side of the central bar 64. Each horizontal bar 66, 68 is arranged in contact against a detection element 34, 38 such that two detection elements 34, 38 arranged in opposition on either side of the transverse median zone 42 of the printed circuit board 20 are arranged in contact against the two horizontal bars 66, 68 of the inverted “T”.

The part of the inverted “T” arranged in opposition to the transverse median zone 42 of the printed circuit board 20 is not in contact with the median zone 42 of the printed circuit board 20. In other words, the two horizontal bars 66, 68 of the inverted “T” thus show a rising stepped profile at the level of their junction with the vertical bar 64, such that they are only in contact with the detection elements 34, 38, and not in contact with the median zone 42 of the printed circuit board 20.

In the longitudinal axis L, each horizontal bar 66, 68 is of a similar length to the length of the detection element 34, 38 with which the horizontal bar 66, 68 is in contact. The control element 18 is a one-piece moulding; in other words, the contact arms 62 of the control element 18 are formed in one piece with the control plate 56.

The printed circuit board 20 is arranged on the support element 22. More specifically, the support element 22 incorporates four retaining studs 70, 72, 74, 76 for the printed circuit board 20. The retaining studs 70, 72, 74, 76, formed in one piece with the support element, are arranged for overall fitting to the four corners of the printed circuit board 20. Specifically, the retaining studs 70, 72, 74, 76 are configured with a cross-shape, arranged level to the support element 22, and engaging in contact with the printed circuit board 20. The four retaining studs 70, 72, 74, 76 are of identical overall height, in the vertical direction.

The printed circuit board 20 is also in contact with a transverse support bar 78, configured with a projecting profile from the support element 22. The transverse support bar 78 is formed in one piece with the support element 22. The printed circuit board 20 lies in contact with the transverse support bar 78 over the full length of its transverse median line MT. The transverse support bar 78 is of sufficient length, in the transverse direction, to engage in contact with the printed circuit board 20 over the full length of the transverse median line MT. The transverse support bar 78, in the vertical direction, is of slightly greater height than the four retaining studs 70, 72, 74, 76.

According to the form of embodiment represented in FIG. 1, each transverse end 30, 32 of the printed circuit board 20 engages in contact with two retaining studs 70, 72, 74, 76, wherein the transverse median zone 42 of the printed circuit board 20 engages in contact with the transverse support bar 78. As a result of the difference in height between the retaining studs 70, 72, 74, 76 and the transverse support bar 78, the printed circuit board 20 is arranged with a slight outward curvature from the support element 22. In order to maintain the slight curvature of the printed circuit board 20 on the support element 22, the retaining studs 70, 72, 74, 76 can incorporate latching means with the printed circuit board 20. Alternatively, in order to maintain the slight curvature of the printed circuit board 20 on the support element 22, the control unit 16 can be subject to light compression between the control panel 10 and a base of the unit housing which is mechanically connected to the control panel.

According to the form of embodiment represented in FIG. 1 and FIG. 2, the series of position detectors 24 permits the identification of the position of the finger of an operator on the control zone 55, and the detection of the finger-slide. The perception by the operator of the acknowledgement of the command executed by a finger-slide is perceptible by the force feedback generated by a vibration of the detection elements 34, 36, 38, 40. More specifically, where the position detectors 24 have detected an operator's finger-slide on the slide-operated control zone 55, an electrical signal is applied to the detection elements 34, 36, 38, 40, such that the latter vibrate. As the detection elements 34, 36, 38, 40 are in contact with the contact arms 62 of the control element, a feedback force is thus perceived by the operator. Moreover, light sources 28 in the control unit 16 permit the illumination of the control zone 55 in which the operator has executed a finger-slide.

Although it is possible not to arrange the detection elements 34, 36, 38, 40 on elastic tabs 44, 46, 48, 50 of the printed circuit board 20, the specific arrangement of the detection elements 34, 36, 38, 40 on elastic tabs 44, 46, 48, 50 permits the amplification of the vibration thereof, thereby accentuating force feedback. The arrangement of the printed circuit board 20 with a slight elevation in relation to the support element 22, also permits the accentuation of the amplitude of the vibrations of the detection elements 34, 36, 38, 40 on the elastic tabs 44, 46, 48, 50.

The detection elements 34, 36, 38, 40 can also permit the determination of the contact force on the control zone 55. This characteristic can permit, for example, the attribution of multiple functions to the sliding-contact control button 12.

The force with which an operator applies their finger-slide to the control zone 55 is transmitted to the detection elements 34, 36, 38, 40 by the contact arms 62. According to the form of embodiment with the contact arms configured as an inverted “T”, the impact of this force is delivered to the transverse median zone 42 of the printed circuit board 20, such that a load is specifically applied to the detection elements 34, 36, 38, 40 at the free end 54 of the elastic tabs 44, 46, 48, 50. The curvature of the printed circuit board 20 permits the achievement of the optimum uniformity of the force applied to the detection elements 34, 36, 38, 40, according to the position of the finger of an operator. In other words, this curvature permits the limitation of acquisition errors for the contact force of the finger of an operator, regardless of the position of the finger on the control zone 55. However, it is possible for the printed circuit board 20 not to be elevated, and likewise for the latter not to be configured in a curved arrangement, wherein acquisition and correction functions for the contact force according to the position of the finger of the operator can be processed by a control device (not represented) which is electrically connected to the control unit 16.

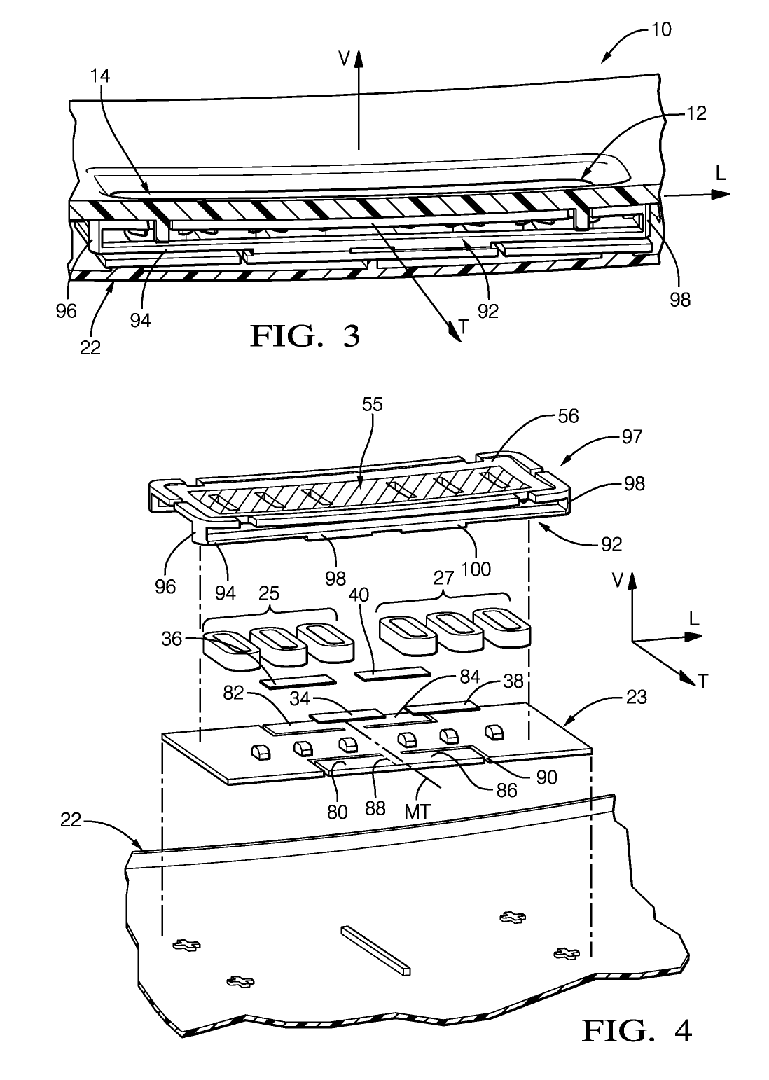

According to FIG. 3 and FIG. 4, a second form of embodiment is represented. This form of embodiment only differs from that represented in FIG. 1 and FIG. 2 in that the contact arm 92 and the elastic tabs 80, 82, 84, 86 are of different geometrical shapes.

The elastic tabs 80, 82, 84, 86 in this form of embodiment only differ from the preceding form of embodiment in that their connecting end 88 and their free end 90 have been interchanged. In other words, the connecting ends 88 of these elastic tabs 80, 82, 84, 86 are arranged directly against the transverse median line MT of the printed circuit board 23.

Although this arrangement of elastic tabs 80, 82, 84, 86 can be appropriate to the above-mentioned embodiment described according to FIG. 1 and FIG. 2, this constitutes an optimum arrangement vis-a-vis the structure of the two contact arms 92 (only one of which is visible) represented in FIG. 3 and FIG. 4.

Each contact arm 92 in the form of embodiment represented in FIG. 3 and FIG. 4 comprises a contact transfer bar 94 arranged longitudinally and parallel to a longitudinal edge of the control plate 56 of the control element 97 and extending over the full length of the control plate 56. The contact transfer bar 94 is arranged under the longitudinal edge of the control plate 56 and is connected at each of its ends to the longitudinal edge of the control plate 56 by a vertical element 96, 98, which constitutes a spacer with the longitudinal edge of the control plate 56. The contact transfer bar 94 is thus uniformly spaced to the longitudinal edge of the control plate 56, such that it is as close as possible to the printed circuit board 23, without contacting the latter.

However, in the vertical direction, the thickness of the contact transfer bar is increased vis-à-vis the detection elements 34, 36, 38, 40 such that it is in continuous contact with said detection elements 34, 36, 38, 40. The increase in thickness of the contact transfer bar thus forms two protuberances 98, 100, each incorporating a contact surface which is in continuous contact with two detection elements 80, 86 arranged on either side of the transverse median zone 42 of the printed circuit board 23.

The force with which an operator slides their finger on the control zone 55 is transmitted to the detection elements 34, 36, 38, 40 by means of the contact arms 92. According to the form of embodiment of the contact arms 92 incorporating a contact transfer bar 94, this force is delivered to the vertical elements 96, 98 arranged at the ends of the longitudinal edges of the control plate 56, and is thus applied specifically to the detection elements 34, 36, 38, 40 at the free end 90 of the elastic tabs 80, 82, 84, 86.

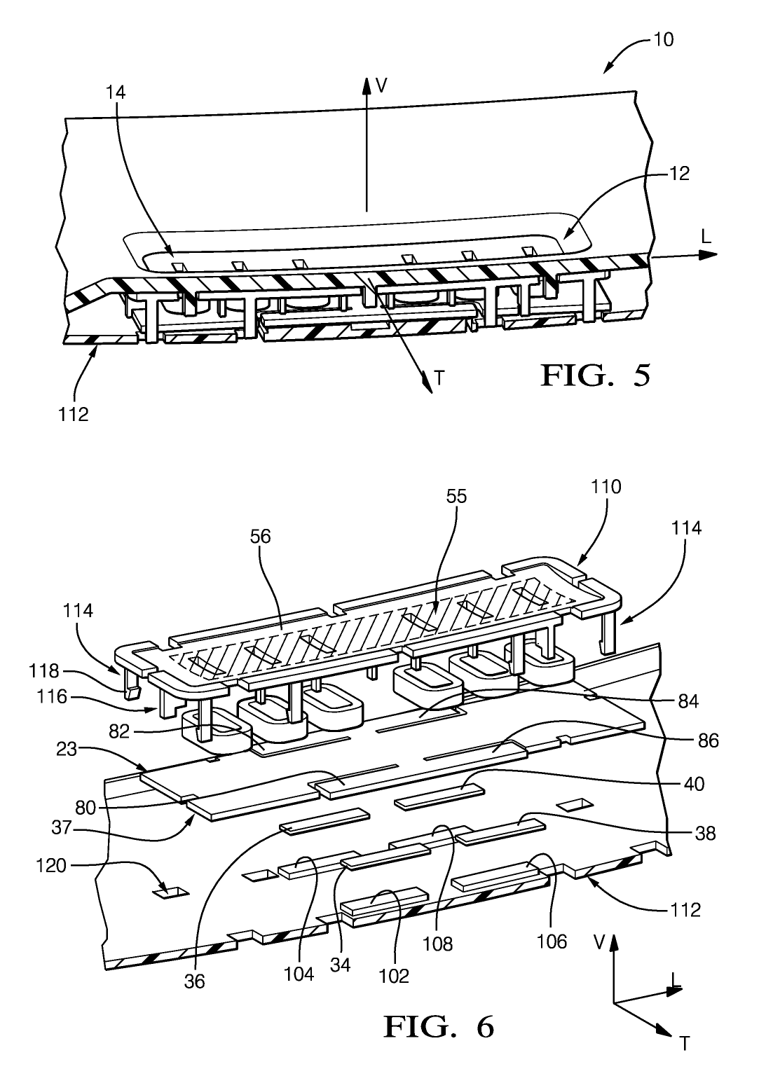

According to FIG. 5 and FIG. 6, a third form of embodiment is represented. This form of embodiment only differs from that represented in FIG. 3 and FIG. 4 in that the detection elements 34, 36, 38, 40 are arranged on the underside 37 of the printed circuit board 23, the control element 110 incorporates no contact arm, and the support element 112 incorporates no transverse support bar.

According to this form of embodiment, the support element 112 incorporates four longitudinal support bars 102, 104, 106, 108 arranged opposite the elastic tabs 80, 82, 84, 86 and of identical overall dimensions to the elastic tabs 80, 82, 84, 86. The four longitudinal support bars 102, 104, 106, 108 are configured with a projecting profile on the support element. The four longitudinal support bars 102, 104, 106, 108 are formed in one piece with the support element 112. The detection elements 34, 36, 38, 40 are arranged on the underside of the elastic tabs 80, 82, 84, 86 and are in permanent contact with the longitudinal support bars 102, 104, 106, 108.

The control element 110 incorporates retaining bars 114 for engagement with the support element 112 and contact bars 116 for the retention of the printed circuit board against the support element. More specifically, the control plate 56 incorporates, along its longitudinal edges, vertical retaining bars 114, the free end of which forms a retaining lug 118 for engagement with the support element 112, in contact with the underside of the support element 112. The retaining lug 118 of each retaining bar 114 is arranged through an opening 120 in the support element 112. Moreover, at each of its two transverse ends, the control plate 56 incorporates a vertical contact bar 116 which is engaged in contact against the printed circuit board 23. Further contact bars are also arranged between the control plate 56 and the printed circuit board 23.

According to this form of embodiment, the printed circuit board 23 is compressed between the control plate 56 and the support element 112. The printed circuit board 23 is also curved between its two transverse ends, as it also rests on the longitudinal support bars 102, 104, 106, 108 which are configured with a projecting profile on the support element 112. When an operator applies a finger-slide to the control zone 55 of the control element 110, the load force applied by the control element 110 and by the support element 112 to the printed circuit board 23 is modified, and is thus detected by the detection elements 34, 36, 38, 40.

Upon the application of an electrical signal to the detection elements 34, 36, 38, 40, the vibration of the latter results in the vibration of the support element 112, wherein the latter is in direct contact with the control element 110 as a result of the retaining bars 114. The vibrations of the detection elements 34, 36, 38, 40 are therefore perceptible by the operator as a feedback force through the control plate 56.

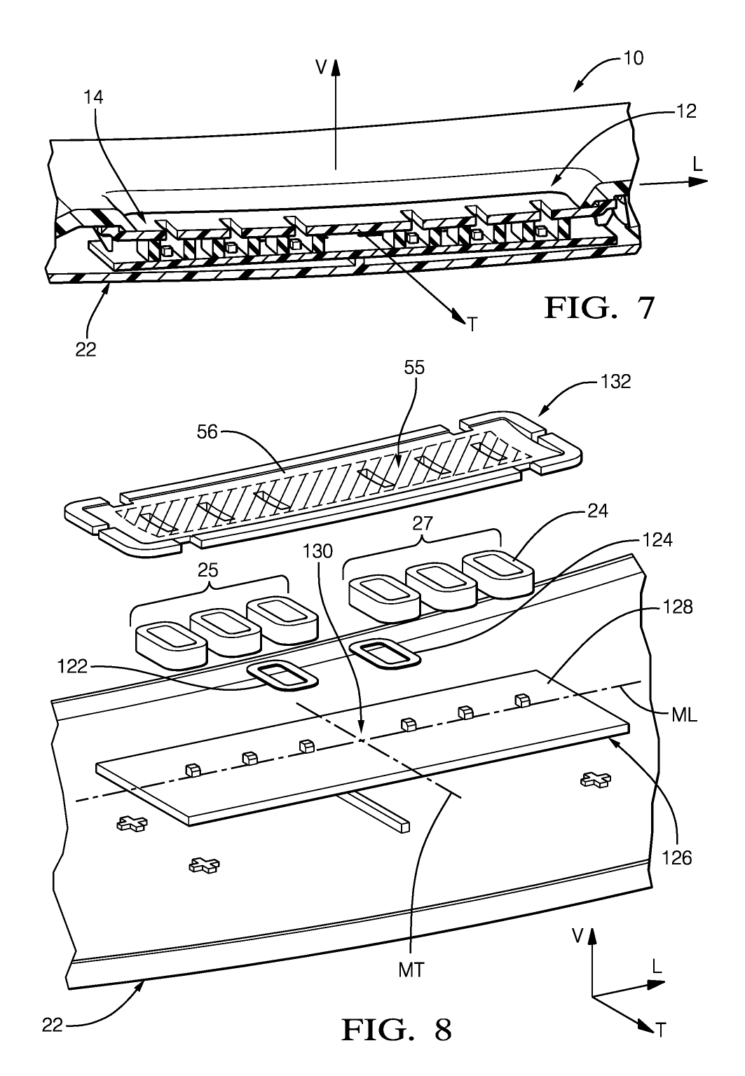

According to FIG. 7 and FIG. 8, a fourth form of embodiment is represented. This specific form of embodiment differs from the first and second form of embodiment, in that the detection elements 122, 124 are arranged on the upper surface 128 of the printed circuit board 126, below position detectors 24. More specifically, the detection elements 122, 124 are of annular design, and are interposed between the position detectors 24 of annular design and the upper surface 128 of the printed circuit board 126. According to this form of embodiment, the printed circuit board 126 incorporates only two detection elements 122, 124, arranged symmetrically on either side of the transverse median line MT of the printed circuit board 126, and directly opposite the transverse median zone 130 of the printed circuit board 126.

The control element 132 incorporates no contact arm formed in one piece with said control plate 56. The mechanical connection between the control plate 56 and the detection elements 122, 124, permitting the detection elements 122, 124 to function as both a contact force sensor and as a haptic actuator, is embodied by the two position detectors 24 under which the detection elements 122, 124 are arranged.

Although the printed circuit board 126 is represented with no elastic tabs, it is also possible for cut-outs to be arranged in the printed circuit board 126 around the annular detection elements 122, 124, in order to form plastic tabs.

It is possible to execute a multitude of further forms of embodiment, according to which the shape of the positon detectors is not annular, and also according to which the position detectors are of types other than capacitive detection sensors including, for example, resistive detection sensors.

Further forms of embodiment are also possible, wherein the control unit is limited to a printed circuit board incorporating a minimum of one series of at least two position detectors and one detection element, wherein the position detectors are mounted in contact against the control element, and the detection element is interposed in contact between the printed circuit board and a connecting component, wherein the connecting component, such as a contact arm, is in direct contact with the control element. The elastic tabs, together with the support elements of the printed circuit board, permit the improved operation of the detection elements, i.e. the improved detection of the contact force associated with the execution by an operator of a finger slide on the control zone, and the improved perception of the feedback force by the operator.

All the forms of embodiment represented permit the achievement of a sliding-contact control unit of limited thickness in the vertical axis, thus permitting the easy integration thereof in numerous electronic control modules in the passenger compartment of a vehicle. More specifically, the use of such a control panel will be observed for electronic roof modules in a vehicle which is generally designed for the lighting of the passenger compartment of the vehicle, or such a control panel will be used for the front-end electronic control modules of the vehicle, including control facilities for the multimedia system or the vehicle air-conditioning system.

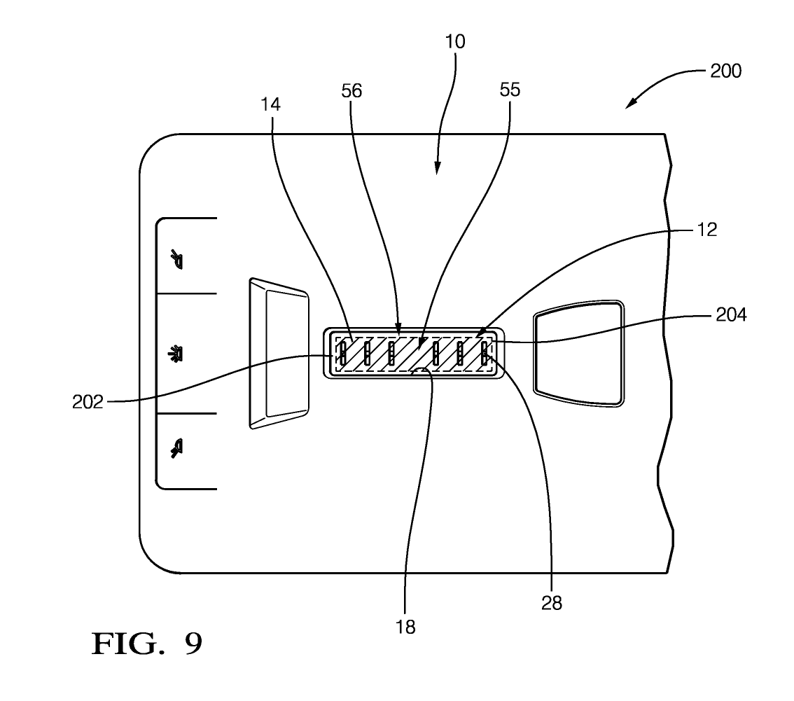

According to FIG. 9, a form of embodiment of an electronic roof module 200 in the passenger compartment of a vehicle is represented. This module 200 is generally designed for the lighting of the front seats of the vehicle. The electronic roof module 200 comprises the control panel 10, equipped with any of the forms of embodiment of the control units described. It incorporates three lighting control buttons and one sliding-contact control button 12. The sliding-contact control button 12 incorporates any one of the forms of embodiment of the control units represented in FIGS. 1, 2, 3, 4, 5, 6, 7 and 8. The control element 18 is arranged in the opening 14 in the control panel 10, thus permitting an operator to access the slide-operated control zone 55.

The execution by an operator of a finger-slide on the sliding-contact control button 12 can permit the activation of between one and six light sources 28, by means of a finger-slide from one transverse end 202 of the control zone 55 to the other end 204. Luminous intensity can be adjusted with respect to the contact force. Acknowledgment of the command thus executed is possible by means of a force feedback effect on the control plate 56, which is perceptible by the operator.

According to the invention, a control method for a sliding-contact control unit 16 in a motor vehicle can comprise a plurality of steps, specifically a step for the detection of finger contact on the control zone 55 by means of the series of position detectors 25, more specifically by means of at least one capacitive detection sensor for the detection of the presence of the finger of the operator. In order to confirm this contact, and thereby considerably reducing spurious detections of contact, the method incorporates a step for the validation of finger contact on the control zone 55 by means of a different detection element 34 from the series of position detectors 25. More specifically, the detection element 34 may be a piezoelectric element, the strain of which by the application of finger contact permits the confirmation of said contact, and also the determination of the contact force of the finger on the control zone 55. The method also comprises a step for the detection of the finger-slide executed by the operator on the control zone 55, by means of the series of position detectors 25, more specifically by means of the series of capacitive detection sensors. The method incorporates the generation of a haptic acknowledgement signal for the finger-slide on the control zone 55, by means of the detection element 34, more specifically by means of the piezoelectric element functioning as a haptic actuator. Finally, the method comprises a step for the actuation of a vehicle command function, according to the travel of the finger-slide on the control zone 55, i.e. according to the distance covered by the finger-slide on the control zone 55.

We claim:

1. A sliding-contact control unit (16) for a motor vehicle, said control unit comprising:
a support element (22);
a printed circuit board (20) arranged on the support element (22); and
a control element (18) covering the printed circuit board (20), wherein the control element defines an operator-controlled finger-slide control zone (55);
the printed circuit board (20) comprising a first series of position detectors (25), said printed circuit board configured to determine a position and a direction of sliding of a finger of an operator, wherein the first series of position detectors (25) is supported against the control element (18) and facing the slide-operated control zone (55);
the printed circuit board (20) comprises at least a first detection element (34), which is simultaneously a contact force sensor and a haptic actuator, wherein the first detection element (34) is interposed in a supporting arrangement between the printed circuit board (20) and a connecting component (61), wherein the connecting component (61) is in direct contact with the control element (18);
characterized in that
the printed circuit board (20) incorporates a first cut-out, forming a first elastic tab (44) upon which the first detection element (34) is arranged.

2. The control unit (16) according to claim 1, characterized in that each detection element (34) is a piezoelectric element.

3. The control unit (16) according to claim 1, characterized in that the first series of position detectors (25) comprises capacitive detection sensors.

4. The control unit (16) according to claim 1, characterized in that
the printed circuit board (20) is of overall rectangular design, in one longitudinal axis (L) and one transverse axis (T),
the control element (18) comprises a control plate (56) of overall rectangular design, upon which the control zone (55) extends longitudinally, in order to permit the detection of a finger-slide on the control zone (55) in the longitudinal direction.

5. The control unit (16) according to claim 4, characterized in that the transverse median zone (42) of the printed circuit board (20) is arranged in contact on a transverse support bar (78), which incorporates a projecting profile on the support element (22), and in that the transverse edges (30, 32) of the printed circuit board (20) are flattened against the support element (22), such that the printed circuit board (20) shows a curved profile.

6. The control unit (16) according to one of claim 4, characterized in that it incorporates a second series of position detectors (27) arranged symmetrically to the first series of positon detectors (25) in relation to the transverse median line (MT) of the printed circuit board (20), and a second detection element (38) arranged symmetrically to the first detection element (34), in relation to the transverse median line (MT) of the printed circuit board (20).

7. The control unit (16) according to claim 6, characterized in that the printed circuit board (20) incorporates a second cut-out, forming a second elastic tab (48) upon which the second detection element (38) is arranged.

8. The control unit (16) according to one of claim 6, characterized in that the connecting component (61) incorporates a first contact arm (62) formed in one piece with the control element (18) and arranged against the first detection element (34) and the second detection element (38).

9. The control unit (16) according to one of claim 6, characterized in that it incorporates a third detection element (36) and a fourth detection element (40), respectively arranged symmetrically to the first detection element (34) and the second detection element (38), in relation to the longitudinal median line (ML) of the printed circuit board (20).

10. The control unit (16) according to claim 9, characterized in that the printed circuit board (20) incorporates a third cut-out and a fourth cut-out, forming a third elastic tab (46) and a fourth elastic tab (50) upon which the third detection element (36) and the fourth detection element (40) are arranged respectively.

11. The control unit (16) according to claim 9, characterized in that the connecting component (61) incorporates a second contact arm, formed in one piece with the control element (18) and arranged against the third detection element (36) and the fourth detection element (40).

12. The control unit (16) according to claim 1, characterized in that the connecting component (61) incorporates at least one position detector (24).

13. The control unit (16) according to claim 1, characterized in that the connecting component (61) incorporates at least one support bar (102), configured with a projecting profile on the support element (22), wherein each detection element (34) is arranged on a support bar (102), wherein the control element (18) comprises means of attachment (114) to the support element (22).

14. The control unit (16) according to claim 13, characterized in that the means of attachment (114) are retention pins, extending from the control element (18) to their free end, wherein each free end incorporates a lug (118) which engages in openings (120) provided in the support element and abuts against the lower surface of the support element (112), such that the printed circuit board (20) is retained by compression between the control element (18) and the support element (22).

15. Electronic roof module (200) in the passenger compartment of a motor vehicle, incorporating the control unit (16) according to one of the preceding claims.

16. A control method for a sliding-contact control unit (16), said method comprising:
detection of finger contact with the control zone (55) by means of a capacitive detection sensor;
confirmation of finger contact with the control zone (55), by means of a piezoelectric element arranged on an elastic tab (44) of the printed circuit board (20);
detection of the finger contact force on the control zone (55), by means of the piezoelectric element;
detection of the finger-slide on the control zone (55), by means of a series of capacitive detection sensors;
generation of a haptic acknowledgement signal for the finger-slide on the control zone (55), by means of the piezoelectric element;
activation of a vehicle command, according to the route of the finger-slide on the control zone (55).
